(19) United States
(12) Patent Application Publication
(10) Pub. No.: US 2015/0015811 A1
(43) Pub. Date: Jan. 15, 2015

(54) TOUCH SCREEN PANEL AND METHOD FOR MANUFACTURING SAME

(71) Applicant: HON HAI PRECISION INDUSTRY CO., LTD., New Taipei (TW)

(72) Inventors: CHIN-YANG WU, New Taipei (TW); SZU-WEI SUNG, New Taipei (TW); WEN-KAI LO, New Taipei (TW); TEN-HSING JAW, New Taipei (TW)

(21) Appl. No.: 14/331,339

(22) Filed: Jul. 15, 2014

(30) Foreign Application Priority Data
Jul. 15, 2013 (TW) 102125303

(51) Int. Cl. G06F 3/041; H05K 3/46; H05K 3/06

(52) U.S. Cl. CPC G06F 3/041; H05K 3/06; H05K 3/4685
USPC 349/12; 216/15

(57) ABSTRACT

A touch screen panel includes a substrate, a plurality of first electrodes formed on the substrate and extending along a first direction, a plurality of second electrodes formed on the substrate and extending along a second direction substantially perpendicular to the first direction; and a plurality of conducting connectors. The conducting connectors are made of a metallic material. A surface of each conducting connector is processed by oxidation treatment for forming oxides, or treated by sulfidizing.

### FIELD

The present disclosure generally relates to a touch screen panel and a method for manufacturing the touch screen panel.

### BACKGROUND

Touch screen panels are an input device that, for example, allows instruction to be input by touching different parts of the screen.

### BRIEF DESCRIPTION OF THE DRAWINGS

Implementations of the present technology will now be described, by way of example only, with reference to the attached figures.

FIG. 1 illustrates a plan view of one embodiment of a touch screen panel having a substrate, a plurality of first electrodes, a plurality of second electrodes, a plurality of insulating layers, and a plurality of conducting connectors.

FIG. 2 illustrates an enlarged view of circled portion II shown in FIG. 1.

FIG. 3 illustrates a cross section view along line III-III of FIG. 2.

FIG. 4 shows a process for manufacturing the touch screen panel of FIG. 1.

FIG. 5 shows a flowchart for manufacturing the touch screen panel of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

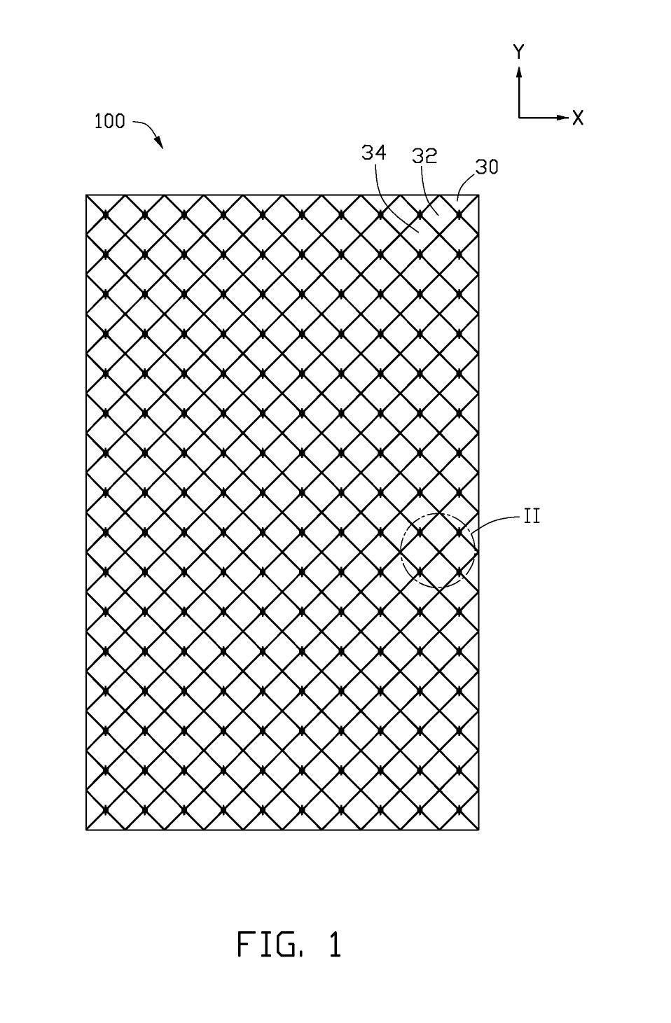

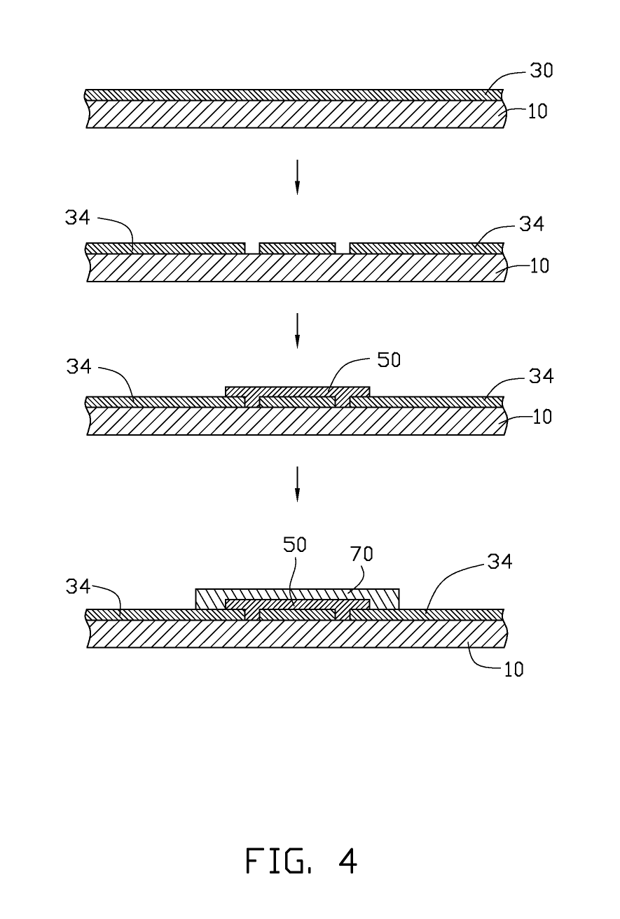

The present disclosure is in relation to a touchscreen. FIGS. 1 and 4 illustrate a touch screen panel 100 of one embodiment including a substrate 10, a plurality of first electrodes 32, and a plurality of second electrodes 34 arranged between the plurality of first electrodes 32.

The first electrodes 32 and the second electrodes 34 can be formed in meshing structures on the substrate 10. The first electrodes 32 can be electrically coupled each other in a first direction X. The second electrodes 34 can be arranged between the first electrodes 32 along a second direction Y, where direction Y intersects with the first direction X, but the second electrodes 34 do not overlap the first electrodes 32. The first electrode 32 and the second electrodes 34 can therefore be insulated from each other. The substrate can be made of a transparent insulation material, such as polyethylene terephthalate (PET), polyimide (PI), or polycarbonate (PC), for example.

The first electrodes 32 and the second electrodes 34 can be formed of a material such as a film of indium tin oxide (ITO), indium-zinc oxide (IZO), zinc oxide (ZnO), carbon nanotubes (CNT), a conductive polymer, or graphene. The substrate 10 can be made of a transparent insulation material, such as PET, PI, or PC for example. The plurality of second electrodes 34 and the plurality of first electrodes 32 can be formed in a transparent electrode material layer 30 which is etched on the substrate 10.

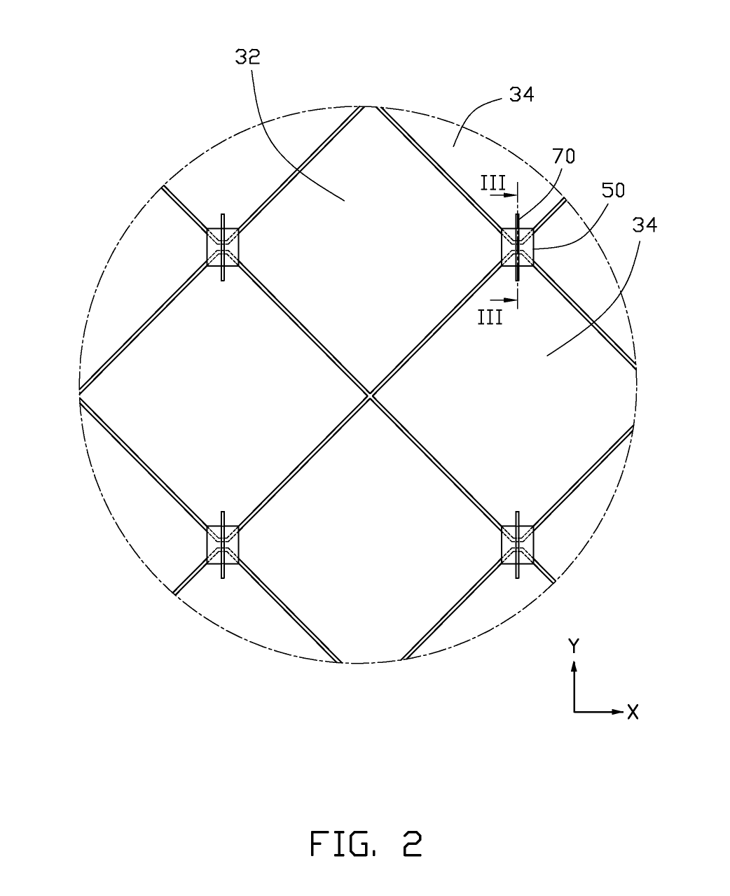

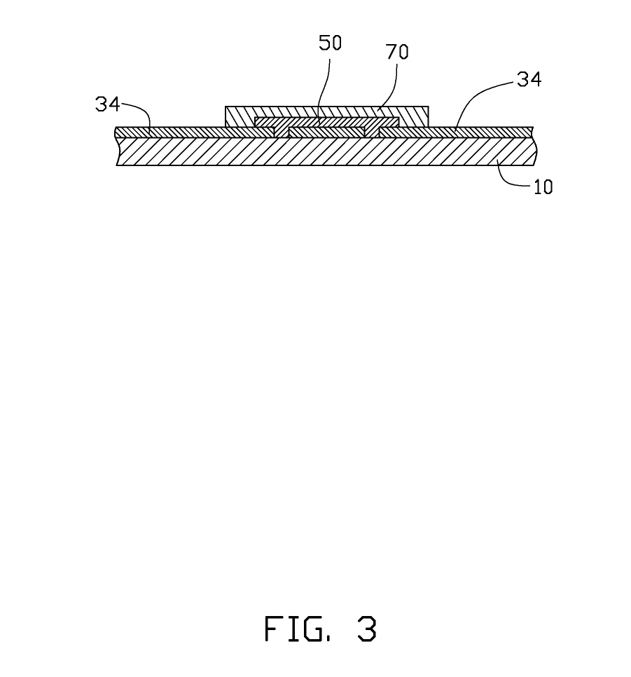

FIGS. 2-3 show a plurality of insulating layers 50 patterned on the plurality of first electrodes 32 and the plurality of second electrodes 34. Each insulating layer 50 can overlap two neighboring second electrodes 34 of the same row along the second direction Y to provide insulation. Each insulating layer 50 can overlap a portion of each of two first electrodes 32, which can be positioned adjacent to the two neighboring second electrodes 34. Each insulating layer 50 can be substantially rectangular in shape. A thickness of each insulating layer 50 can be about 1 μm to 3 μm. Each insulating layer 50 can cover a portion of each of the two neighboring second electrodes 34. In other embodiments, the insulating layer 50 can be other shapes, such as triangular, hexagonal, circular, and others.

A plurality of conducting connectors 70 can be formed on the plurality of insulating layers 50. Each conducting connector 70 can be formed on one insulating layer 50, and two ends of the conducting connector 70 protrude from the insulating layer 50 to electrically couple with the two neighboring second electrodes 34 in the same row. The second electrodes 34 arranged in the same row along the second direction Y can thereby be electrically coupled to each other. The conducting connectors 70 are made of a metallic material. A surface of each conducting connector 70 can be processed by oxidation to form oxides, or treated by sulfidizing to form sulfides. Oxides and sulfides have low reflectivity in the visible spectrum, such that a light-scattering property of the conducting connectors 70 can be improved. In the illustrated embodiment, the metallic material can be silver or copper and the conducting connectors 70 and the insulating layers 50 can be formed via an ink jet printing method. The insulating layers 50 are made of thermosetting, UV-type and transparent organic materials, such as PI.

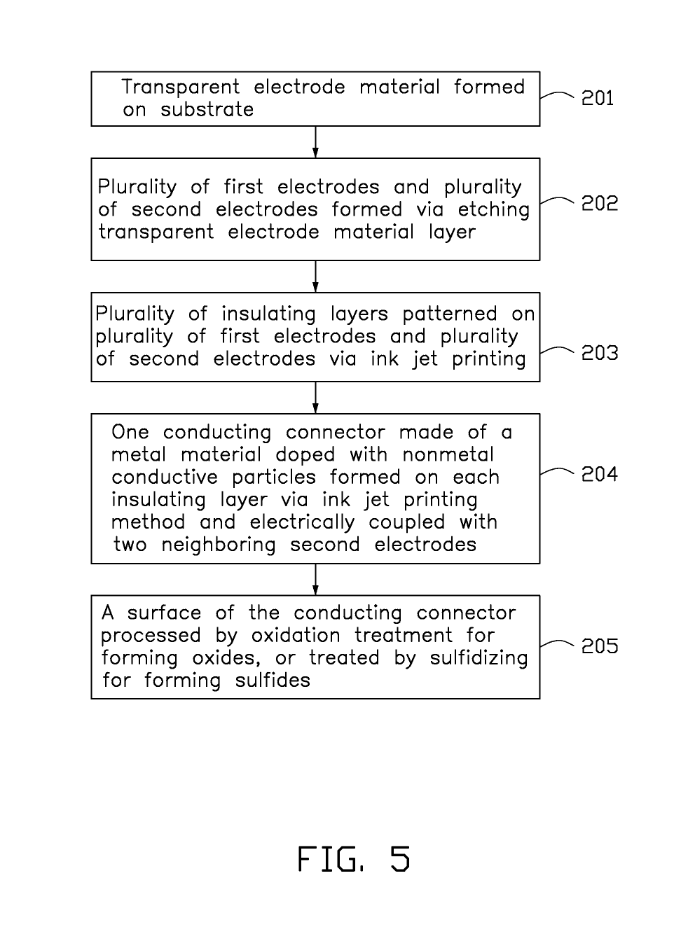

FIGS. 4-5 illustrate the process and method for manufacturing the touch screen panel.

In block 201, the transparent electrode material layer is formed on the substrate. In the illustrated embodiment, the transparent electrode material layer on the substrate is made of a material such as ITO, IZO, ZnO, CNT, a conductive polymer, or graphene, which is transparent and has electric conductivity. The substrate can be made of transparent insulation material such as PET, PI, or PC, for example. The transparent electrode material layer can be coated onto the substrate by a sputtering coating method.

In block 202, the plurality of first electrodes and the plurality of second electrodes are formed via etching the transparent electrode material layer. The first electrodes and the second electrodes can be formed in meshing structures on the substrate. The first electrodes can be electrically coupled to each other along the first direction X. The second electrodes can be dispersed between the first electrodes so as not to overlap any of the first electrodes and can be formed to have their own separated patterns along the second direction Y. The second electrodes can thereby be insulated from each other. In present embodiment, the transparent electrode material layer can be etched via a chemical etching method. The first electrodes in the same row along the first direction X can be electrically connected with each other, and the first electrodes in the same row along the second direction Y can be insulated from each other.

In block 203, the plurality of insulating layers are patterned on the plurality of first electrodes and the plurality of second electrodes via ink jet printing. Each insulating layer can be located on at least two neighboring second electrodes along the second direction Y. The insulating layer can be substantially rectangular in shape. In other embodiments, the insulating layer can be other shapes, such as triangular, hexagonal, circular or others.

In block 204, one conducting connector, made of a metallic material, is formed on each insulating layer via the ink jet printing method, and electrically coupled with the two neighboring second electrodes. In the illustrated embodiment, the metallic material can be silver or copper.

In block 205, a surface of the conducting connector is processed by oxidation to form oxides, or is treated by sulfidizing to form sulfides.

In other embodiments, the plurality of insulating layers can be omitted, the conducting connectors can be prepared via a chemical doping method, and each conducting connector can be electrically coupled with the two neighboring second electrodes via a wire bonding method without any electrical contact being made with the first electrodes. Thus, the step 203 can be omitted when the conducting connector is wire bonded with the two neighboring second electrodes.

The embodiments shown and described above are only examples. Many details are often found in the art such as the other features of a substrate. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A touch screen panel comprising:
a substrate;
a plurality of first electrodes formed on the substrate and extending in a first direction;
a plurality of second electrodes formed on the substrate and extending in a second direction that is substantially perpendicular to the first direction; and
a plurality of conducting connectors being made of a metallic material, wherein each of the plurality of conducting connectors has a surface being processed by an oxidation treatment for forming oxides or being treated by sulfidizing.

2. The touch screen panel of claim 1, wherein the metallic material is silver or copper.

3. The touch screen panel of claim 1, further comprising a plurality of insulating layers formed on the plurality of first electrodes and the plurality of second electrodes, each insulating layer formed on two neighboring second electrode among the plurality of second electrodes, each conducting connector is positioned on the corresponding insulating layer, and two ends of the conducting connector protrude from the insulating layer to electrically couple with the two neighboring second electrodes.

4. The touch screen panel of claim 3, wherein the plurality of insulating layers is made of thermosetting, UV-type and transparent organic materials.

5. The touch screen panel of claim 1, wherein the plurality of first electrodes and the plurality of second electrodes are made of one from the group comprising indium tin oxide film, indium-zinc oxide, zinc oxide, carbon nanotubes, a conductive polymer, and graphene.

6. A method of manufacturing a touch screen panel, comprising:
forming a transparent electrode material layer on a substrate;
etching the transparent electrode material layer and forming a plurality of first electrodes and the plurality of second electrodes arranged between the plurality of first electrodes; forming a plurality of conducting connectors made of a metal material, each conducting connector electrically coupling with two neighboring second electrodes among the plurality of second electrodes in a same row without contacting the first electrodes; and
a surface of each conducting connector being processed by oxidation to form oxides, or treated by sulfidizing to form sulfide.

7. The touch screen panel of claim 6, wherein the metal material is silver or copper.

8. The manufacturing method of claim 6, further comprising forming a plurality of insulating layers on the plurality of first electrodes and the plurality of second electrodes after forming a plurality of first electrodes and a plurality of second electrodes, wherein each conducting connector is formed on one insulating layer, and two ends of the conducting connector protrude from the insulating layer to electrically couple with the two neighboring second electrodes.

9. The touch screen panel of claim 8, wherein the plurality of insulating layers are made of thermosetting, UV-type and transparent organic materials.

10. The manufacturing method of claim 9, wherein the plurality of conducting connectors are formed on the plurality of insulating layers via an ink jet printing method.

11. The manufacturing method of claim 9, wherein the plurality of insulating layers are formed on the plurality of second electrodes via an ink jet printing method.

12. The manufacturing method of claim 8, wherein the transparent electrode material layer is coated on the substrate by a sputtering coating method.
